(19) United States
(12) Patent Application Publication
(10) Pub. No.: US 2008/0199993 A1
(43) Pub. Date: Aug. 21, 2008

(54) Protective layer in device fabrication

(76) Inventors: Benjamin Heying, Fullerton, CA (US); Ioulia Smorchkova, Lakewood, CA (US); Vincent Gambin, Gardena, CA (US); Robert Coffie, Camarillo, CA (US)

Correspondence Address: PATTI, HEWITT & AREZINA LLC, ONE NORTH LASALLE STREET, 44TH FLOOR, CHICAGO, IL, 60602, US

(21) Appl. No.: 11/708,779

(22) Filed: Feb. 21, 2007

(51) Int. Cl. H01L 21/338

(52) U.S. Cl. 438/172

(57) ABSTRACT

An improved method for fabricating an HEMT device having active device layers deposited on a semiconductor substrate. In an embodiment, the improved method comprises the steps of depositing an AlN layer over the active device layers using a relatively low temperature vacuum process to form an amorphous layer protecting the active device layers from unnecessary exposure to fabrication processes, and selectively forming openings in the AlN layer to expose portions of the active device layers for imminent process steps.

### BACKGROUND

The reliability and performance of Nitride-based high electron mobility transistor (HEMT) semiconductors are very sensitive to damage at the surface of the semiconductor. The fabrication process can cause damage to an exposed surface by creating point defects, oxide layers, and contamination.

### SUMMARY

The invention in one implementation encompasses an improved method for fabricating an HEMT device having active device layers deposited on a semiconductor substrate. In an embodiment, the improved method comprises the steps of depositing an AlN layer over the active device layers using a relatively low temperature vacuum process to form an amorphous layer protecting the active device layers from unnecessary exposure to fabrication processes, and selectively forming openings in the AlN layer to expose portions of the active device layers for imminent process steps.

The invention in another implementation encompasses an improved fabrication system for an HEMT device having active device layers deposited on a semiconductor substrate. In an embodiment, the improved fabrication system comprises means for depositing an AlN layer over the active device layers using a relatively low temperature vacuum process to form an amorphous layer protecting the active device layers from unnecessary exposure to fabrication processes, and means for selectively forming openings in the AlN layer to expose portions of the active device layers for imminent process steps.

### DESCRIPTION OF THE DRAWINGS

FIG. 1 depicts a semiconductor device having an amorphous AlN cap.

FIG. 2 illustrates source and drain windows opened in the device of FIG. 1.

FIG. 3 depicts source and drain contacts formed in the device of FIG. 2.

FIG. 4 shows a gate window opened in the AlN cap of the device of FIG. 3.

FIG. 5 illustrates gate formation by deposition of gate metal in the device of FIG. 4.

FIG. 6 depicts the device of FIG. 5 with the remaining AlN layer removed.

FIG. 7 shows the surface of the completed device passivated with SiN.

FIG. 8 is a flow chart of a semiconductor fabrication process.

### DETAILED DESCRIPTION

During device manufacture, unprotected surfaces can be affected by exposure to the fabrication environment. Air exposure leads to the formation of thin oxide layers on the surface of the semiconductor. Vacancies and other point defects are created during the high temperature anneal used to create ohmic contacts, as well as plasma cleaning treatments. Finally, diffusion of contaminants into the semiconductor can occur due to residues left on the surface during processing. Oxide layers, point defects, and contamination have been found to cause electron trapping at the surface that degrades performance and reliability.

A protective layer that can be selectively removed during the fabrication process can shield the surface from damage due to oxidation, high-temperature processing steps, plasma cleans, and contamination.

Low temperature AlN (aluminum nitride) deposited in situ under vacuum as part of the growth process protects the semiconductor surface from exposure to the fabrication environment. Due to the large difference in crystal structure between the AlN and the semiconductor, openings in the AlN layer can be selectively etched (wet or dry etching) to expose the semiconductor surface in the area that is immediately to undergo a processing step. For example, in an embodiment, immediately before depositing gate metal, an opening in the AlN is etched so that the gate metal is deposited on the barrier surface. This effectively eliminates any surface exposure of the area under the gate prior to this gate metallization step.

AlN is grown at low temperature in the deposition system under vacuum. The layer is designed to be polycrystalline/amorphous to avoid cracking. During the fabrication process, windows within the AlN are opened using wet or dry etching to expose the surface just before a processing step, only in the area required for the processing step (i.e., ohmic metal deposition, gate metal deposition, SiN deposition).

Using the process described herein, the semiconductor surface remains protected (covered with AlN) until just before metal deposition, SiN passivation, and during all high-temperature anneals. The surface is capped with AlN before exposure to air. The AlN can be easily removed before processing steps due to its selectivity during etching. In addition, the AlN can be grown thick without cracking.

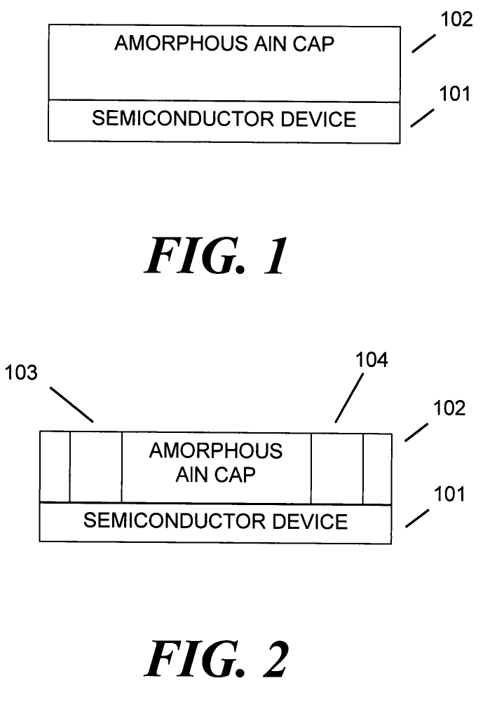

FIG. 1 depicts a semiconductor device 101 having an amorphous AlN cap 102. In an embodiment, the AlN layer is deposited using molecular beam epitaxy, or MBE. MBE is used to deposit the AlN cap 102 rather than chemical vapor deposition (CVD) or physical vapor deposition (PVD). MBE, CVD, and PVD are very different in how they deposit a material on a substrate. In the MBE technique, highly purified atomic species are created in source cells far from the substrate. During deposition, these atomic species are allowed to move through the vacuum and impinge on the substrate, creating a thin film. Due to the high reactivity of the atomic species, very little energy (heating) is required at the substrate to create the reacted film. Therefore, the deposition of the AlN can be carried out over a wide range of substrate temperatures that can change the crystal structure of the AlN from amorphous (low temperature) to highly crystalline (high temperature). This ability to tune the crystalline nature of the AlN is unique to MBE and is advantageous because it allows one to change the stress within the film, and to change the selectivity of the AlN etch process. CVD-generated layers have to be deposited at higher temperatures in order to create the reactive species. PVD-generated layers are deposited at lower temperatures, and utilize damaging plasmas near the substrate that can cause point defects in the semiconductor. In addition, to deposit PVD- or CVD-generated AlN films on nitride semiconductors grown by MBE, the substrate would have to be exposed to the air environment before the AlN deposition, allowing for the formation of an oxide layer. By depositing the AlN film in situ by MBE, the semiconductor surface is not exposed to air, and is protected from oxide formation.

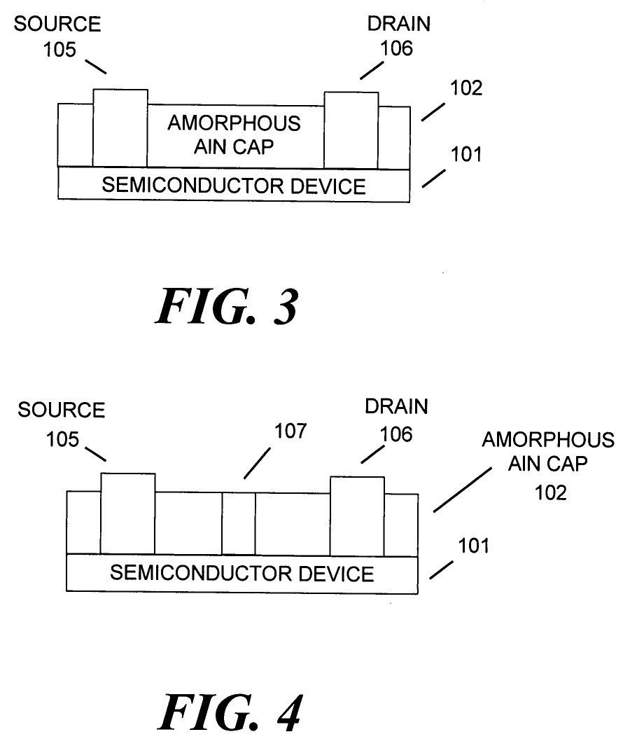

Windows are then opened through the AlN cap for source and drain contacts, as shown in FIG. 2, in which a source window 103 and drain window 104 are illustrated. Source and drain contacts 105, 106 are then fabricated, as depicted in FIG. 3. Next, a gate window 107 is opened in the AlN cap 102 as shown in FIG. 4.

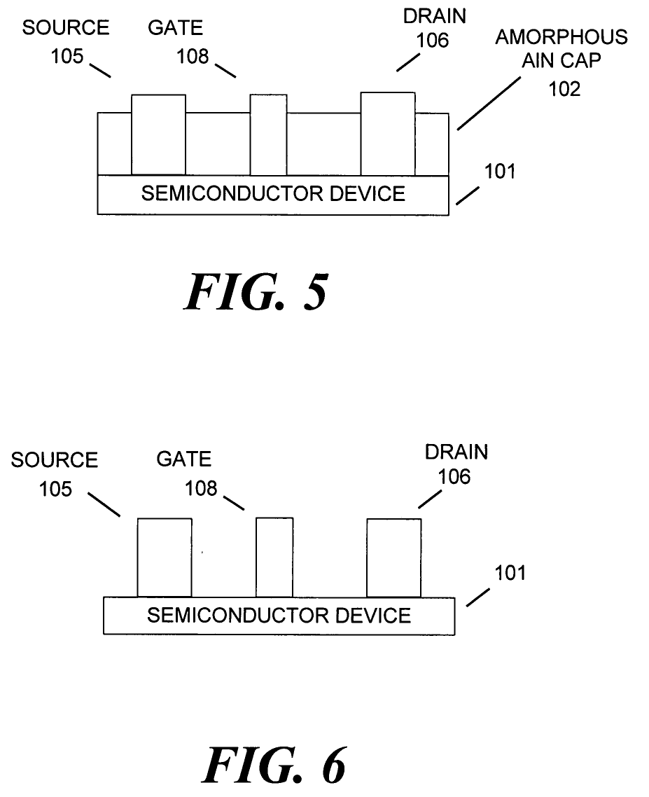

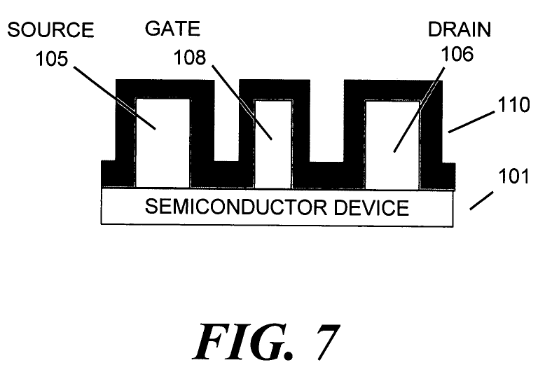

FIG. 5 illustrates the formation of a gate 108 by deposition of gate metal. The remaining AlN layer 102 is then removed as illustrated in FIG. 6. FIG. 7 shows that the surface of the completed device is then passivated with SiN (silicon nitride) 110.

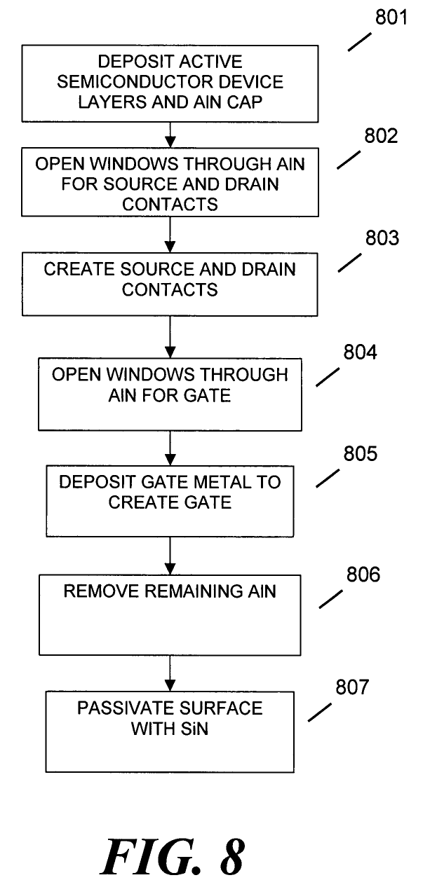

As shown in FIG. 8, a semiconductor fabrication process for a HEMT device begins by depositing active semiconductor layers and an AlN cap layer in step 801. In the subsequent step (802) windows are opened through the AlN, using a mild etchant, for source and drain contacts. Source and drain contacts are then formed in step 803.

In the next step (804), a window is opened through the AlN for the gate, and gate metal is then deposited (in step 805) to create the gate for the device. In the subsequent step (806), the remaining AlN is removed. In step 807, the surface of the device is passivated with SiN.

The steps or operations described herein are intended as examples. There may be many variations to these steps or operations without departing from the spirit of the invention. For instance, the steps may be performed in a differing order, or steps may be added, deleted, or modified.

Although examples of implementations of the invention have been depicted and described in detail herein, it will be apparent to those skilled in the relevant art that various modifications, additions, substitutions, and the like can be made without departing from the spirit of the invention and these are therefore considered to be within the scope of the invention as defined in the following claims. For example, the AlN layer described herein could be deposited by MBE on semiconductor films that are deposited using other epitaxial techniques, such as MOCVD or HVPE.

MOCVD, or metalorganic chemical vapor deposition, is a form of chemical vapor deposition used for epitaxial growth. In MOCVD, compound semiconductors are grown on a substrate, in a reactor, by introducing an organic compound in combination with a metal hydride. An epitaxial layer is formed by final pyrolysis at the substrate surface. This differs from MBE in that the epitaxy is deposited by a chemical reaction and not physical deposition. Instead of vacuum, the reactor environment moderate pressure. HVPE, or hydride vapor phase epitaxy (HVPE), is a similar process utilizing carrier gasses that may include Ammonia, Hydrogen, and various Chlorides. In the case where the semiconductor films are deposited using one of the above-described techniques, the surface would be exposed to the air environment before being placed into the MBE vacuum chamber for deposition of the AlN layer.

What is claimed is:

1. An improved method for fabricating an HEMT device having active device layers deposited on a semiconductor substrate, the improvement comprising:
(a) depositing an AlN layer over the active device layers using a relatively low temperature vacuum process to form an amorphous layer protecting the active device layers from unnecessary exposure to fabrication processes; and
(b) selectively forming openings in the AlN layer to expose portions of the active device layers for imminent process steps.

2. The improved method of claim 1, wherein the step of depositing an AlN layer further comprises the step of depositing an AlN layer using molecular beam epitaxy.

3. The improved method of claim 1, wherein the step of selectively forming openings in the AlN layer further comprises the step of opening windows in the AlN layer just before a processing step, and only in the area required for the processing step.

4. The improved method of claim 3, wherein the processing step is selected from the group of processing steps consisting of:
ohmic metal deposition;
gate metal deposition; and
SiN deposition.

5. The method in accordance with claim 1, further comprising the step of removing any remaining portions of the AlN layer after all process steps requiring selective etching of the AlN layer have been completed.

6. The method in accordance with claim 5, further comprising the step of forming a passivation layer of SiN over the device.

7. A method for fabricating an HEMT device having active device layers deposited on a semiconductor substrate, the method comprising the steps of:
(a) depositing an AlN layer over the active device layers using a relatively low temperature vacuum process to form an amorphous layer protecting the active device layers from unnecessary exposure to fabrication processes;
(b) opening windows through the AlN layer for source and drain contacts using selective etching;
(c) forming source and drain contacts for the device;
(d) opening a window through the AlN layer for a gate using selective etching;
(e) depositing gate metal to create a gate for the device;
(f) removing any remaining portions of the AlN layer; and
(g) forming a passivation layer of SiN for the device.

8. The method in accordance with claim 7, wherein the step of depositing an AlN layer over the active device layers further comprises the step of depositing an AlN layer using molecular beam epitaxy.

9. An improved fabrication system for an HEMT device having active device layers deposited on a semiconductor substrate, the improved fabrication system comprising:
means for depositing an AlN layer over the active device layers using a relatively low temperature vacuum process to form an amorphous layer protecting the active device layers from unnecessary exposure to fabrication processes; and
means for selectively forming openings in the AlN layer to expose portions of the active device layers for imminent process steps.

10. The improved fabrication system of claim 9, wherein the means for depositing an AlN layer further comprises means for depositing an AlN layer using molecular beam epitaxy.

11. The improved fabrication system of claim 9, wherein the means for selectively forming openings in the AlN layer further comprises means for opening windows in the AlN layer just before a processing step, and only in the area required for the processing step.

12. The improved fabrication system of claim 11, wherein the processing step is selected from the group of processing steps consisting of:
ohmic metal deposition;
gate metal deposition; and
SiN deposition.

13. The improved fabrication system of claim 9, further comprising means for removing any remaining portions of the AlN layer after all process steps requiring selective etching of the AlN layer have been completed.

14. The improved fabrication system of claim 13, further comprising means for forming a passivation layer of SiN over the device.

15. Apparatus for fabricating an HEMT device having active device layers deposited on a semiconductor substrate comprising:
means for depositing an AlN layer over the active device layers using a relatively low temperature vacuum process to form an amorphous layer protecting the active device layers from unnecessary exposure to fabrication processes;
means for opening windows through the AlN layer for source and drain contacts using selective etching;
means for forming source and drain contacts for the device;
means for opening a window through the AlN layer for a gate using selective etching;
means for depositing gate metal to create a gate for the device;
means for removing any remaining portions of the AlN layer; and
means for forming a passivation layer of SiN for the device.

16. The apparatus of claim 15, wherein the means for depositing an AlN layer over the active device layers further comprises means for depositing an AlN layer using molecular beam epitaxy.

17. An HEMT device having active device layers deposited on a semiconductor substrate, the HEMT device fabricated by the steps of:
(a) depositing an AlN layer over the active device layers using a relatively low temperature vacuum process to form an amorphous layer protecting the active device layers from unnecessary exposure to fabrication processes; and
(b) selectively forming openings in the AlN layer to expose portions of the active device layers for imminent process steps.

18. The HEMT device of claim 17, wherein the AlN layer is adapted to be deposited using molecular beam epitaxy.

19. The HEMT device of claim 17, wherein openings in the AlN layer are adapted to be formed by opening windows in the AlN layer just before a processing step, and only in the area required for the processing step.

20. The HEMT device of claim 19, wherein the processing step is selected from the group of processing steps consisting of:
ohmic metal deposition;
gate metal deposition; and
SiN deposition.

21. The HEMT device of claim 17, wherein fabrication of the device further comprises the step of removing any remaining portions of the AlN layer after all process steps requiring selective etching of the AlN layer have been completed.

22. The HEMT device of claim 21, wherein fabrication of the device further comprises the step of forming a passivation layer of SiN over the device.

23. A method for fabricating an HEMT device, the method comprising the steps of:
(a) forming active device layers on a semiconductor substrate utilizing a vapor phase deposition process within a reactor that contains the vapor phase of desirable chemical constituents under elevated pressure;
(b) removing the semiconductor substrate from the reactor, such that the active device layers are exposed to an air environment;
(c) placing the semiconductor substrate into a vacuum chamber and depositing an AlN layer over the active device layers using a relatively low temperature vacuum process to form an amorphous layer protecting the active device layers from unnecessary exposure to fabrication processes;
(d) opening windows through the AlN layer for source and drain contacts using selective etching;
(e) forming source and drain contacts for the device;
(f) opening a window through the AlN layer for a gate using selective etching;
(g) depositing gate metal to create a gate for the device;
(h) removing any remaining portions of the AlN layer; and
(i) forming a passivation layer of SiN for the device.

24. The method in accordance with claim 23, wherein the step (a) of forming active device layers utilizing a vapor phase deposition process further comprises the step of forming active device layers utilizing metalorganic chemical vapor deposition.

25. The method in accordance with claim 23, wherein the step (a) of forming active device layers utilizing a vapor phase deposition process further comprises the step of forming active device layers utilizing hydride vapor phase epitaxy.
